(19) United States
(12) Patent Application Publication
(10) Pub. No.: US 2024/0124726 A1
(43) Pub. Date: Apr. 18, 2024

(54) Nanoparticle Ink Based Patterning Of Inorganic Materials

(71) Applicant: The Trustees of the University of Pennsylvania, Philadelphia, PA (US)

(72) Inventors: Akhila Mallavarapu, Philadelphia, PA (US); Chavez FK Lawrence, Philadelphia, PA (US); Cherie R. Kagan, Bala Cynwyd, PA (US)

(21) Appl. No.: 18/483,862

(22) Filed: Oct. 10, 2023

Related U.S. Application Data
(60) Provisional application No. 63/378,980, filed on Oct. 10, 2022.

(51) Int. Cl. C09D 11/037; G03F 7/00

(52) U.S. Cl. CPC C09D 11/037; G03F 7/0002

(57) ABSTRACT

Provided are nanostructure imprinting processes that utilize dispersions of nanoparticles in aqueous solvents. Also provided are nanostructure imprinting processes that utilize temperature-sensitive solvents that can be thinned via application of temperature. Such solvents allow for formation of nanostructures of particular height.

### CROSS-REFERENCE TO RELATED APPLICATIONS

The present application claims priority to and the benefit of U.S. patent application Ser. No. 63/378,980, “Nanoparticle Ink Based Patterning Of Inorganic Materials” (filed Oct. 10, 2022). All foregoing applications are incorporated herein by reference in their entireties for any and all purposes.

### GOVERNMENT RIGHTS

This invention was made with government support under 1941529 awarded by the National Science Foundation. The government has certain rights in the invention.

### TECHNICAL FIELD

The present disclosure relates to the field of nanostructures and to the field of imprint-based manufacturing.

### BACKGROUND

Inexpensive nanopatterning of inorganic materials such as metals, metal oxides, semiconductors and insulators on a variety of substrates can enable a wide range of applications such as optics, photonics, sensing, electronics, catalysis, thermoelectric and energy devices, and the like. Flat optics with sub-wavelength nanostructures has revolutionized the fields of sensing, AR/VR, and the like. Patterning of nanostructures is typically accomplished using traditional CMOS processes such as deposition, lithography and etch, subtractive processing and/or high temperature processing. However, many applications of optical metasurfaces are highly cost-sensitive, require flexible or curved surfaces with low thermal budgets, and would benefit from fabrication with high throughput inexpensive processes. Accordingly, there is a long-felt need in the art for improved methods for making optical metasurfaces.

### SUMMARY

In this work, we demonstrate, inter alia, a single-step direct nanoparticle (NP) ink-based imprint process for fabricating metasurfaces (e.g., TiO₂-based dielectric metasurfaces) using nanoparticle inks on rigid and flexible polymeric substrates, paving the way for high volume and low-cost manufacturing of inorganic nanostructures. In particular, a TiO₂ nanocrystal-based imprint process with aqueous nanocrystal inks significantly reduces chemical consumption during manufacturing, and uses environmentally benign consumables, such as water and TiO₂, and can be extended to biocompatible and biodegradable material systems. This is particularly useful for applications requiring high volume manufacturing, such as passive optical sensors for precision agriculture, single-use devices such as contact lenses and biosensors, and lightweight optical elements.

The present disclosure first provides a nanostructure imprinting process, comprising: contacting a template stamp to an amount of a dispersion disposed on a surface, the template stamp having a pattern thereon, the dispersion comprising an aqueous solvent having a plurality of nanoparticles dispersed therein, the nanoparticles optionally having a diameter of from about 2 nm to about 1000 nm, and the contacting being performed such that the dispersion at least partially fills the pattern of the template stamp; and effecting at least partial removal of the aqueous solvent so as to give rise to structures that comprise the nanoparticles and that substantially conform to the pattern of the template stamp, the structures optionally defining a metasurface.

Also provided is a structure, the structure made according to the present disclosure.

Further disclosed is a system, comprising: an amount of a dispersion comprising an aqueous solvent having a plurality of nanoparticles dispersed therein, the nanoparticles optionally having a diameter of from about 2 nm to about 1000 nm; a template stamp having a pattern thereon; a surface; and an applicator, the applicator configured to dispense an amount of the dispersion onto the surface, the system being configured to contact the template stamp to dispensed dispersion so as to give rise to structures that comprise the nanoparticles and substantially conform to the pattern of the template stamp.

Also provided is a metasurface, comprising a substrate; and a plurality of structures superposed on the substrate, a structure comprising a plurality of nanoparticles associated together, a structure having a characteristic dimension in the range of from about 5 nm to about 1000 nm.

Further provided is a nanostructure imprinting process, comprising: contacting a template stamp to an amount of a dispersion disposed on a surface, the template stamp having a pattern thereon, the dispersion (i) comprising a temperature-thinning solvent and (ii) having a plurality of nanoparticles dispersed therein, the nanoparticles optionally having a diameter of from about 2 nm to about 1000 nm, and the contacting being performed such that the dispersion at least partially fills the pattern of the template stamp; and effecting at least partial removal of the solvent so as to give rise to structures that comprise the nanoparticles and that substantially conform to the pattern of the template stamp, the structures optionally defining a metasurface.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

In the drawings, which are not necessarily drawn to scale, like numerals can describe similar components in different views. Like numerals having different letter suffixes can represent different instances of similar components. The drawings illustrate generally, by way of example, but not by way of limitation, various aspects discussed in the present document. In the drawings:

FIG. 1: (a) Custom imprint tool developed for creating the process flow in a single step. (b) Examples of TiO₂ and ZnO nanocrystal inks and their imprints, showing photos of the imprinted samples and SEM images of the nanostructures. (c) AFM image showing the height of imprinted TiO₂ nanostructures.

FIG. 2: Example structures according to the present disclosure.

FIG. 3: Illustrative disclosure related to metasurfaces with dynamic Mie and quasi guide mode (QGM) resonances.

FIG. 4: (a) Photograph of the custom imprint tool composed of a pneumatic press, die set, and pressure, temperature, and humidity sensors mounted in an environmentally isolated chamber. (b) Schematic overview of the NC imprint process: [1] aqueous TiO₂ NC dispersions are drop-cast on a substrate, [2] the template is placed onto and pressed into the dispersion as the solvent evaporates at uniform pressure and room temperature, and [3] the template is released, yielding TiO₂ NC metasurfaces. The template is reused for subsequent imprints. (c) Schematic and cross-sectional SEM images of exemplar imprinted nanopillars on a Si substrate with and without a residual NC layer. (d) AFM image of imprinted TiO₂ NC nanopillars. (e) Photographs of imprinted TiO₂ NC metasurfaces fabricated on flexible polymer and rigid glass substrates.

FIG. 5: (a) Plot of waveguide (or residual layer) thickness as a function of imprint pressure for a 25 wt % NC dispersion, where (*) denotes delamination of the imprinted features from the Si substrate. (b) Cross-sectional SEM images of the Si masters used for cPDMS templates, and imprinted TiO₂ NC metasurfaces fabricated at various imprint pressures with a 25 wt % NC dispersion, where the yellow line indicates the Si substrate. (c) Plot of pillar height as a function of NC concentration at a 10 psi imprint pressure using the 1:2 (red squares) and 2:1 (blue diamond) AR templates, where the grey area denotes the presence of a residual layer. (d) Cross-sectional SEM images of imprinted features at various NC ink concentrations with a constant, 10 psi imprint pressure. The yellow line indicates the Si substrate.

FIG. 6: (Center) Photograph of an imprinted TiO₂ NC metasurface fabricated from a 25 wt % NC ink at a 10 psi imprint pressure (scale bar: 0.5 cm) with position markings 1-8, selected for (1-8) AFM imaging.

FIG. 7: (a) Experimental transmission spectra of TiO₂ NC metasurfaces printed using a 25 wt % NC ink yielding 100 nm pillars with no waveguide (green), 100 nm pillars on a 100 nm waveguide (blue), and 150 nm pillars on a 100 nm waveguide (pink). Simulated transmission spectrum for pillars on a 100 nm residual layer (red dotted). (b) Simulation of the ED-1 and MD-1 QGMs as a function of waveguide thickness for 100 nm pillars. (c) Experimental spectra of the QGM resonances for the NC pillar/waveguide and (d) the wavelengths of MD-1 and ED-1 resonant modes as a function of the environment RI, used to calculate the metasurface sensitivities.

FIG. 8. Photographs of PDMS templates (a) as cured, (b) no silane treatment—after 5 imprints, (c) silane treated—after 5 imprints.

FIG. 9. Photographs of imprints using 200 μL of 25 wt % NC ink at 10 psi for a print time of 4 h for at various relative humidity (RH) of: (a) 5% - 15% RH where the imprint has large nonuniformity and cracking due to the fast rate of water evaporation resulting in poor print quality, (b) 25% - 40% RH, showing an exemplar print where evaporation rate is co-optimized with the print time of ˜4 h, and (c) >50% RH where water evaporation is too slow for the given imprint time causing a large region of the imprinted sample to remain wet after template removal.

FIG. 10. Photograph of sample printed at 80 psi pressure, showing cracks due to the excessive pressure deforming the cPDMS template during imprinting.

FIG. 11. Top-down SEM images for imprints with 25 wt % NC inks at (a) 2 psi and (b) lOpsi imprint pressure, showing the presence or absence of a residual layer thickness.

FIG. 12. Cross-sectional SEM images for imprints with 10 psi imprint pressure, showing large residual layer thickness variation at (a) 35 wt % and (b) 50 wt % TiO₂ NC ink concentrations.

FIG. 13. Flow curves showing viscosity vs shear rate for the 5 wt %, 15 wt %, and 25 wt % aqueous TiO₂ NC dispersions. Samples are measured using a stress-controlled rheometer (DHR-3, TA Instruments).

FIG. 14. (a) Comparison of pillar heights for (b) as-imprinted, and (c) patterned features post NH₄SCN ligand exchange (LE), shows a reduction in pillar height due to densification of the NC structures.

FIG. 15. Refractive Index of printed TiO₂ NC films—as imprinted, after NH₄SCN ligand exchange, and after RTA anneal.

FIG. 16. Simulated dependence of the transmission spectra on NC pillar height in the (a) absence, and (b) presence of a 100 nm coupled waveguide. Dashed red and blue lines correspond to pillars heights of 160 nm and 300 nm, respectively. The dashed green line corresponds to a pillar height of 100 nm on a 100 nm waveguide. (c) Simulated transmission for 160 nm (blue) and 300 nm (red) tall NC pillars and 100 nm NC pillars coupled to a 100 nm thick waveguide (green).

FIG. 17. Simulated electric (top row) and magnetic (bottom row) field profiles at the 616 nm (left column) and 595 nm (right column) resonances for the all-NC QGM structure described in FIG. 11a. The colors represent the intensity of the fields on an absolute scale while the arrows show the direction of the instantaneous real part of the fields in the simulated structure.

FIG. 18. (a) Experimental transmission spectra of TiO₂ metasurfaces composed of NC pillars (green), NC pillars on a 150 nm sputtered TiO₂ waveguide (blue), and simulated transmission spectrum for pillars on the waveguide (red dotted). (b) Experimental spectra of the QGM resonances for the NC pillar on a sputtered waveguides and (c) the wavelengths of MD-1 and ED-1 resonant modes as a function of the environment RI, used to calculate the metasurface sensitivities.

FIG. 19. Simulated electric (top row) and magnetic (bottom row) field profiles at the 723 nm (left column) and 823 nm (right column) resonances for the sputtered waveguide QGM structure. The colors represent the intensity of the fields on an absolute scale while the arrows show the direction of the instantaneous real part of the fields in the simulated structure.

FIG. 20. (A) Photograph of large area imprinted sample with a titania paste comprising titania nanoparticles and terpineol solvent. (B) Cross-section SEM images of sample above, showing showing high aspect ratio nanopillars on a thick residual layer. (C) Cross-section SEM images of a patterned sample, showing high aspect ratio nanopillars on a thin residual layer, on a silicon substrate.

### DETAILED DESCRIPTION OF ILLUSTRATIVE EMBODIMENTS

The present disclosure may be understood more readily by reference to the following detailed description of desired embodiments and the examples included therein.

Unless otherwise defined, all technical and scientific terms used herein have the same meaning as commonly understood by one of ordinary skill in the art. In case of conflict, the present document, including definitions, will control. Preferred methods and materials are described below, although methods and materials similar or equivalent to those described herein can be used in practice or testing. All publications, patent applications, patents and other references mentioned herein are incorporated by reference in their entirety. The materials, methods, and examples disclosed herein are illustrative only and not intended to be limiting.

The singular forms “a,” “an,” and “the” include plural referents unless the context clearly dictates otherwise.

As used in the specification and in the claims, the term “comprising” can include the embodiments “consisting of” and “consisting essentially of” The terms “comprise(s),” “include(s),” “having,” “has,” “can,” “contain(s),” and variants thereof, as used herein, are intended to be open-ended transitional phrases, terms, or words that require the presence of the named ingredients/steps and permit the presence of other ingredients/steps. However, such description should be construed as also describing compositions or processes as “consisting of” and “consisting essentially of” the enumerated ingredients/steps, which allows the presence of only the named ingredients/steps, along with any impurities that might result therefrom, and excludes other ingredients/steps.

As used herein, the terms “about” and “at or about” mean that the amount or value in question can be the value designated some other value approximately or about the same. It is generally understood, as used herein, that it is the nominal value indicated ±10% variation unless otherwise indicated or inferred. The term is intended to convey that similar values promote equivalent results or effects recited in the claims. That is, it is understood that amounts, sizes, formulations, parameters, and other quantities and characteristics are not and need not be exact, but can be approximate and/or larger or smaller, as desired, reflecting tolerances, conversion factors, rounding off, measurement error and the like, and other factors known to those of skill in the art. In general, an amount, size, formulation, parameter or other quantity or characteristic is “about” or “approximate” whether or not expressly stated to be such. It is understood that where “about” is used before a quantitative value, the parameter also includes the specific quantitative value itself, unless specifically stated otherwise.

Unless indicated to the contrary, the numerical values should be understood to include numerical values which are the same when reduced to the same number of significant figures and numerical values which differ from the stated value by less than the experimental error of conventional measurement technique of the type described in the present application to determine the value.

All ranges disclosed herein are inclusive of the recited endpoint and independently of the endpoints. The endpoints of the ranges and any values disclosed herein are not limited to the precise range or value; they are sufficiently imprecise to include values approximating these ranges and/or values.

As used herein, approximating language can be applied to modify any quantitative representation that can vary without resulting in a change in the basic function to which it is related. Accordingly, a value modified by a term or terms, such as “about” and “substantially,” may not be limited to the precise value specified, in some cases. In at least some instances, the approximating language can correspond to the precision of an instrument for measuring the value. The modifier “about” should also be considered as disclosing the range defined by the absolute values of the two endpoints. For example, the expression “from about 2 to about 4” also discloses the range “from 2 to 4.” The term “about” can refer to plus or minus 10% of the indicated number. For example, “about 10%” can indicate a range of 9% to 11%, and “about 1” can mean from 0.9-1.1. Other meanings of “about” can be apparent from the context, such as rounding off, so, for example “about 1” can also mean from 0.5 to 1.4. Further, the term “comprising” should be understood as having its open-ended meaning of “including,” but the term also includes the closed meaning of the term “consisting.” For example, a composition that comprises components A and B can be a composition that includes A, B, and other components, but can also be a composition made of A and B only. Any documents cited herein are incorporated by reference in their entireties for any and all purposes.

When metals and dielectric materials are patterned into periodic arrays of nanostructures, interaction between light and the nanostructures provides opportunities for wavefront engineering. The type of interaction and the modulation strength depend on the specific geometry of individual nanostructures in the array (also described as meta-atoms), their arrangement in the array, and the materials used. Tuning these variables can enable applications in flat optics, photonics, sensing, structural color, etc. at length scales that were not possible previously. These applications have been demonstrated with both metal and dielectric nanoresonator arrays. Patterning nanoscale features allows for observing these phenomena in visible and infrared wavelengths, which is crucial for a variety of applications such as optical elements such as filters and lenses, wearable contact lenses, remote sensing, etc.

Metasurfaces are typically made using traditional CMOS fabrication techniques such as e-beam and photolithography, physical and chemical vapor deposition and plasma etching, which limit its applicability for cost-sensitive applications as well as limited compatibility to a broader range of substrates. Nanoimprint lithography has been demonstrated as an inexpensive alternative to e-beam lithography for sub-wavelength patterning of metasurfaces, however, it still requires multiple process steps including deposition and plasma etch of the dielectric material. There is a need for scalable and inexpensive manufacturing of high aspect ratio nanostructures with dielectric materials of high refractive indices. This is an area of active research, with an emphasis on single-step nanofabrication with dielectric sol-gel inks, followed by high temperature annealing. Improved optical performance was explored by a push to increase nanoparticle loading and decrease sol-gel or resin in the final nanostructures, thereby reducing the impact of the lower refractive index resin on the overall refractive index of the nanostructures. However, this requires high temperature post process annealing which limits the substrates that can be patterned.

### Direct Nanoparticle Imprint Process

Traditional nanopatterning methods consist of multiple process steps such as deposition, resist spincoat and patterning, resist develop, etch, and lift-off, which increase cost and reduce yield. Further, deposition and etch steps require expensive vacuum-based equipment and have limited compatibility to a broader range of substrates, and thus cannot be readily scaled to cost-effective roll-to-roll nanofabrication. In contrast, use of solution-processable nanoparticles (including amorphous, single crystal, and polycrystalline nanoparticles) allows for creating metasurfaces made of inorganic materials in a single inexpensive process step.

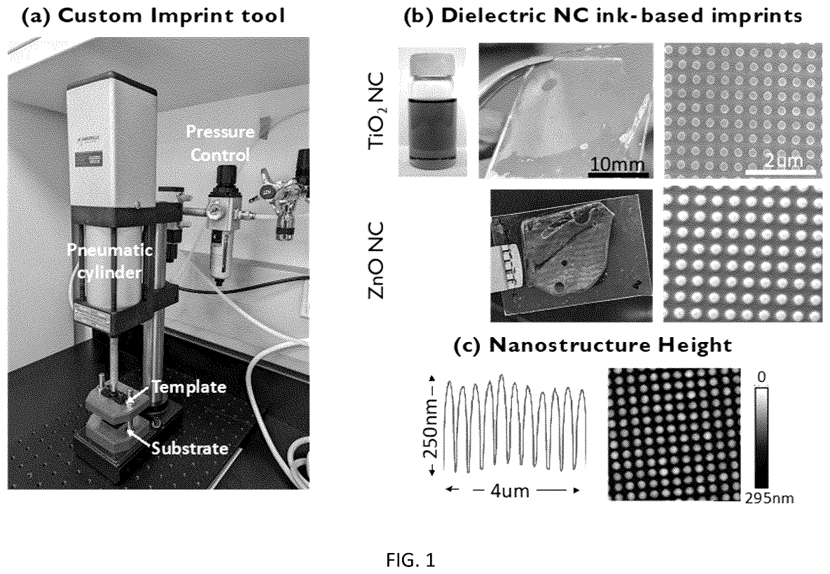

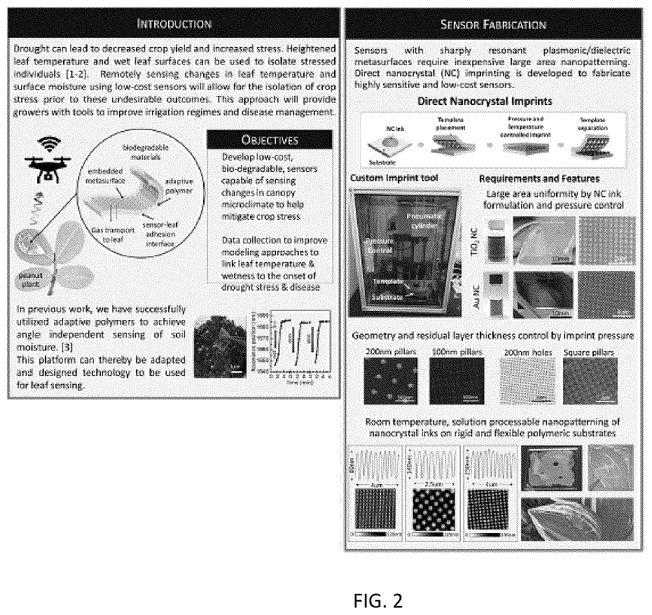

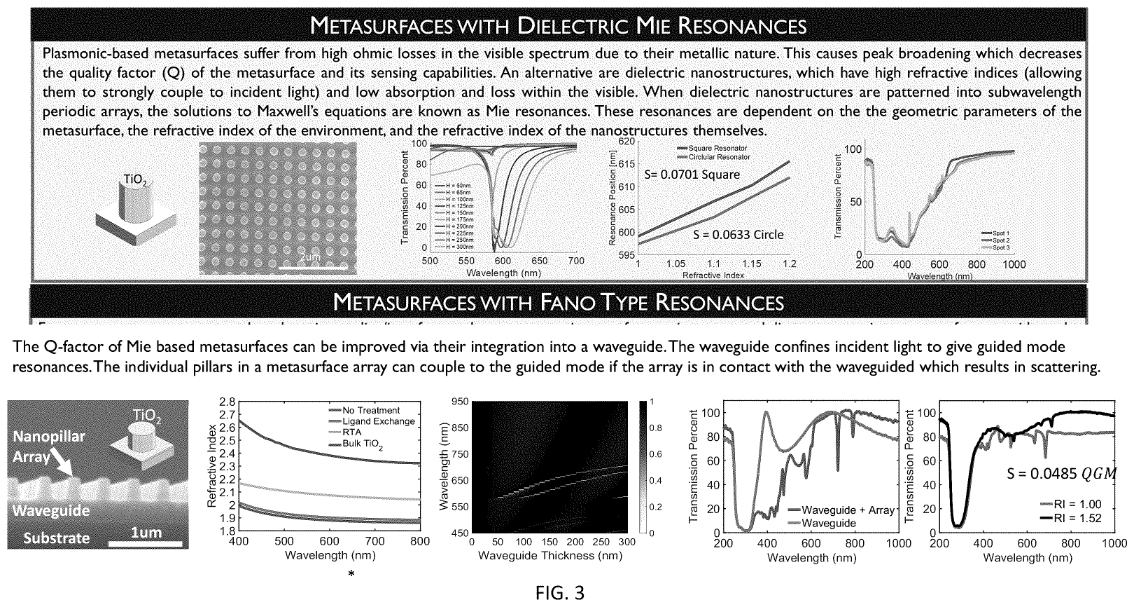

To this end, provided here is a direct nanoparticle (NP) imprinting process to fabricate the metasurfaces in a single step, thereby increasing throughput and reducing fabrication costs (FIG. 1a). To achieve large-area uniformity independent of pattern geometry and material, a custom imprint tool (FIG. 1B) was developed with the ability to control relevant process knobs such as automatic pressure control, temperature control, template and substrate placement and planarity, and ease of using various nanoparticle ink formulations.

Nanoimprint lithography is a patterning process where a stamp with desired nanostructures is brought in contact with a polymer layer on a substrate, where the polymer layer is the resist that is patterned. The stamp is pressed on the substrate, and exposed to high temperatures and/or UV light to cure the resist and transfer the stamp pattern to the polymeric resist. The transferred pattern depends on various parameters such as the resist composition, thickness, stamp feature geometry, pressure, temperature, UV light intensity and imprint time. The height of the pattern is determined by the depth of the pattern in the stamp. A residual layer of polymer can be present below the patterned features, and this layer is typically removed using plasma etching. The thickness of the residual layer can be controlled by tuning the imprint parameters and thickness of the initial resist layer.

In the disclosed process, an aqueous nanoparticle ink is used instead of a polymeric resist, and the ink is deposited on a substrate before bringing the stamp in contact with the ink and substrate. Herein is described an example the fabrication and process parameter space for achieving desired patterns in metal oxides (and other materials; metal oxides are used herein as exemplary only) while controlling their aspect ratio imprints and residual layer thickness.

In some embodiments, the patterned structures (which can be metal oxides) can ask as an etch mask for etching into the substrate material, thereby increasing the aspect ratio of the features and adding a parameter to tune the device performance and/or functionality. For instance, TiO₂-imprinted features on a silicon substrate can be exposed to Si plasma etch chemistries such as SF₆, BC₁₃, XeF₂, and the like, resulting in higher aspect ratio TiO₂/Si pillars. Similarly, TiO₂-imprinted features on glass, sapphire, and other substrates can be exposed to substrate etch chemistry to create TiO₂/substrate features. Polymer substrates can be etched using O₂ plasma with the patterned metal oxide masks. Adaptive polymer substrates can be etched with patterned TiO₂ to create TiO₂/polymer nanostructures, which in turn can increase device sensitivity. Thus, structures formed according to the disclosed process can be used to mask the covered parts of the substrate, thereby exposing the uncovered parts of the substrate for etching or other surface treatment, e.g., application of a hydrophilic and/or hydrophobic coating.

### Parameter Space for Reliable Nano-Imprints

To achieve control over residual layer thickness and height of imprinted nanoparticle-based structures, multiple templates having different aspect ratios and surface energies were fabricated. The template geometry and surface energy, the imprint pressure, and the nanoparticle dispersion concentration were found to have particular effect on imprint quality. Below are certain illustrative factors that affect imprint quality, as well as the characterization methods used to quantify imprint quality.

Template: The template used for the nanoimprint process can be made of a rigid or flexible material, and its properties such as porosity, gas permeability, surface functionalization, feature geometry (pattern, size, resolution), and feature depth can be controlled. The template can be degassed prior to and/or during imprint. Degassing during imprint can be performed by, e.g., placing the template in a vacuum prior to imprint, or by using a vacuum chuck during imprint. Example template materials include, e.g., PDMS, soft and hPDMS, glass, hybrid templates made of glass and PDMS, silicon, nickel, and anodized aluminum oxide (AAO). Template materials can be flexible or rigid. A master template can be fabricated in silicon using e-beam lithography, direct write, self-assembly, block copolymer lithography, plasma etch, metal assisted chemical etch, lift-off, and the like. Template features can have patterns of varying pattern depths, in addition to patterns with varying size, pitch and shapes.

Substrates: Rigid substrates such as silicon, glass, quartz, sapphire, SiC, GaN can be used. The substrates can be flat or curved. Flexible substrates such as polymer films, adaptive polymers (whose refractive index changes with respect to tailored environmental conditions), paper, cellulose, etc. can be used. Further, the substrates may be prepatterend prior to direct nanoparticle imprint, where the pre-patterning can include microstructures such as pillars, holes, or gratings. The substrates may be pre-processed to enable bonding of the nanoparticles to the substrate.

Nanoparticle ink (which can also be termed a dispersion): Aqueous dispersions containing TiOx nanocrystals of various concentrations can used as nanoparticle inks. Examples include, e.g., rutile- TiO₂ in water, anatase TiO₂ in water, mixtures of rutile and anatase TiO₂ in water. Inks can include nanoparticles dispersed in water that are amorphous, poly- or single crystal; metal, dielectric, metal oxides, insulators, semiconductors, and the like; nanoparticles can also doped. Without being bound to any particular embodiment or theory, nanoparticle materials can include, e.g., Au, Cu, Ag, ZnO, ITO, VOX, lead halide, CdS, Si, and the like. A nanoparticle can have a cross-sectional dimension in the range of from about 2 to about 500 nm.

It should be understood that carriers (which can be termed “nanoparticle inks”) used for imprinting of nanostructures can exhibit a range of properties. The viscosity of the inks can range from low water-like viscosity of ˜1 cp (centipoise) (for inks) to high viscosities of ˜100,000 cp (for pastes)

The viscosity of the carrier can vary. For example, the viscosity can be comparatively high (almost a solid) at room temperature to comparatively low (for example, appx. 0 cP) at higher temperatures. Heating—such as heating at less than 200 deg. C.—can be used to attain a desired viscosity during the imprint process. Such a desired viscosity can be, for example, less than 500 cP. Higher viscosities can arise from, for example, a comparatively high loading of nanoparticles and/or a comparatively high viscosity of solvent materials.

The solvent in a carrier can be, for example, water. Water has a viscosity in the range of about 1 cP, and has a boiling point of 100 deg. C. The solvent can also include terpineol, including an isomer thereof α-terpineol—which has a viscosity or about 10 cp at 100 deg. C. and a boiling point of around 218 deg. C.—is considered suitable. The solvent can, like terpineol, have a temperature-controlled viscosity. The solvent can also include, for example, an alcohol or glycol. Polyethylene glycol, ethanol, butanol, and the like are considered suitable. It should be understood that a carrier can include one solvent or a plurality of solvents. As but one example, a carrier can include ethanol and α-terpineol. Cresols are also suitable solvents.

The viscosity of the solvent—and/or of the carrier—can be in the range of from about 0.01 cP to about 100,000 cP (at room temperature), and all intermediate values. For example, the viscosity can be from about 0.01 cP to about 100,000 cP, or from about 1 cP to about 50,000 cP, or from about 5 cP to about 10,000 cP, or from about 10 cP to about 5,000 cP, or even from about 100 cP to about 1000 cP. The boiling point of a solvent can be, for example, from about 10 deg. C. to about 400 deg. C, and all intermediate values. For example, the boiling point can be from about 10 to about 400 deg. C. or from about 25 to about 200 deg. C., or from about 50 to about 150 deg. C.

A carrier can be dispersed before imprinting. Such dispersion can be accomplished by, for example, any one or more of spin-coating, doctor blading, drop-casting, or imprinting with a blank unpatterned template.

An example carrier is a carrier that includes water as the solvent and includes TiO₂ nanocrystals at greater than 30% by weight in the carrier. Another example carrier is a carrier that includes α-terpineol as the solvent and that includes TiO₂ nanocrystals.

Nanoparticle ink: The nanoparticles can have long- or short-chain ligands, although the nanoparticles can also be ligand-free. Example (non-limiting) ligands include PVP, poly(ethylene glycol) [PEG], polystyrene, OA, OAm, —OH, —COOH, citrate, and the like. For instance, TiO₂ nanocrystals with -OH ligands can be dispersed in water to create aqueous NC dispersions. Dispersions with -OH terminated NCs can be made by using KOH to strip ligands and achieve aqueous dispersions.

Nanoparticle ink: Water can be used as a solvent for TiO₂ nanocrystal imprints. Other solvents that the nanoparticles are dispersed in can be one or more of polar and non-polar solvents such as water, methanol, ethanol, NMP, and the like. One can also add polymers such as chitosan, PVA, PEG, and the like in the dispersion.

Imprint: The imprint process can include modulation and control of ink drop placement or jetting or spincoating or doctor blade coating, template placement, pressure, temperature, humidity, speed of motion of template, imprint time, UV curing, template separation, as example parameters. The template and substrate can be held in place using vacuum, and the vacuum can further enhance evaporation of solvents (for permeable templates made of permeable materials) during the imprint process. The parameters can be controlled to vary the residual layer thickness of the pattern from no residual layer to films of about 5 nm to about 200 nm of nanoparticles underlying the formed structures. The tuning of a residual layer underneath the nanostructures, as well as the nanostructure aspect ratio, shows the versatility of this process.

Imprint: The process can be performed to place structures on rigid or flexible substrates, and the process can be applied in roll-to-roll systems. Post patterning, and processes such as ligand-exchange, thermal anneal, high pressure, and the like can be used to compact the patterned nanoparticles. Further (e.g., for materials such as TiO₂), the patterned substrate can be exposed to UV light to burn off ligands.

Post patterning processes: Low temperature processing to improve optical properties including one or more of: (i) Ligand exchange by immersing the patterned substrate in solutions containing one or more of: SCN, NOBF₄, NH₄Cl, Na₂S, and the like; (ii) comparatively low temperature (e.g., <150° C.) annealing of ligand exchanged samples to further remove polymers or ligands and increase inorganic metal oxide content in the patterned substrates; and (iii) ligand stripping process to remove ligands, e.g., by using KOH.

### TiO₂ Nanocrystal Imprints

Dielectric metasurfaces made from titanium dioxide (TiO₂) are of particular interest due to TiO₂'s high refractive characteristics and its exceptionally low losses which allows for higher quality factors (Q-factor) compared to metasurfaces that use metallic resonators. Deposition and patterning of TiO₂ structures is typically accomplished using traditional CMOS processes.

TiO₂ metasurfaces have been demonstrated via sol-gel based imprints, but this process requires high temperature anneals which limit material compatibility, and results in porous, rough, UV-sensitive features with residual layers, thereby limiting their optical performance and durability. Here, we demonstrate an environmentally benign single-step direct nanocrystal ink-based imprint process without any sol-gel mixtures or high temperature annealing steps to get high refractive index TiO₂ imprints. The process can be tailored to achieve high aspect ratio pillars necessary for efficient coupling of light to the metasurface. Further, the low temperature processing enables imprinting of metasurfaces on flexible polymeric substrates. This is demonstrated by experimental characterization and optical simulations of TiO₂ nanocrytal-based metasurfaces imprinted on rigid and flexible polymeric substrates, paving the way for high volume, low-cost and green manufacturing of flat optical metasurfaces.

The metasurfaces can be imprinted on flexible polymers, which allows for a roll-to-roll manufacturing roadmap for scaling this process while achieving CMOS-fab-level optical performance for a fraction of the cost. Further, this process significantly reduces chemical consumption during manufacturing, and uses environmentally benign consumables such as water and TiO₂ and can be extended to biocompatible and biodegradable material systems that can benefit from TiO₂'s corrosion-resistance, high hardness and fracture toughness. This is particularly important for applications requiring high volume manufacturing, such as passive optical sensors for precision agriculture, single-use devices such as contact lenses and biosensors, and lightweight optical elements.

### Additional Disclosure

We report a room temperature, environmentally benign, water-based, single-step direct nanoimprint process to pattern dielectric metasurfaces using aqueous titanium dioxide (TiO₂) nanocrystal (NC) inks, which are free of polymer additives or non-aqueous solvents typically used in nanofabrication. The metasurfaces are composed of TiO₂ NC structures with a high refractive index of 1.94±0.02 at 543 nm. TiO₂ NC metasurfaces are designed to resonate at visible wavelengths and are fabricated as two-dimensional nanopillar gratings atop waveguides. Guided mode resonances within the waveguide couple to the overlaying gratings and scatter into free space, forming high quality (Q) factor, quasi-guided mode (QGM) resonances. Electric and magnetic QGM resonances are observed and their environmental refractive index sensitivities (S) are measured to be 69.1 nm/RIU and 70.4 nm/RIU, respectively, with a figure of merit (FOM)=Q×S>3000. The use of water-based inks and the room temperature processing allows integration of TiO₂ NC metasurfaces on rigid and flexible, polymeric substrates.

Optical metasurfaces composed of subwavelength structures are of great interest due to their potential for strong light-matter interactions and wavefront manipulation. There is particular interest in metasurfaces operating within the visible spectrum to enable devices and systems such as displays, colorimetric remote sensing, flat lenses, color filters, and detectors. The material system can influence operational characteristics of metasurfaces as it determines the type of radiative mode excited by incident light. Plasmonic metasurfaces utilize metallic nanoresonators and exhibit strong light-matter interaction, however, the performance of their devices in the visible is hindered by loss from intraband electronic transitions.

To avoid these losses, dielectric metasurfaces, particularly those made from TiO₂, have shown promise. TiO₂ has a high refractive index (RI) and is exceptionally low loss, yielding metasurfaces with higher quality (Q) factors compared those fabricated from metallic counterparts. Another important consideration for the operation of metasurfaces is the geometry, i.e., the size and shape of the individual resonators and the pitch and motif of the unit cell.

Solution-based methods provide an approach to realize low-cost, scalable nanopatterning of dielectric metasurfaces on rigid, curved, or flexible substrates. Existing print approaches can include polymer additives in the nanostructures, as well as high porosity and roughness, which reduce the RI contrast and Q-factor of the metasurfaces. High-temperature post-imprint anneals are used to densify the films to increase the RI, however, this limits the selection of substrate materials that can be patterned to those that can withstand high temperatures.

In contrast, colloidal NC dispersions—which can be free of polymer additives—can be used. Here, we present an example imprint tool and an additive-free imprint process using aqueous TiO₂ NC inks to achieve large-area nanoimprinted structures designed to enable optical resonances in the visible. By controlling fabrication parameters such as imprint pressure and NC concentration, we tune the geometry and optical responses of the printed metasurfaces. This process can be free of UV or high-temperature processing, and it reduces chemical consumption during manufacturing, uses environmentally benign consumables such as water and TiO₂, and can be extended to biocompatible and biodegradable substrates.

### Methods

### Tool

The custom imprint tool is built using a benchtop pneumatic arbor press and die set from Janesville Tool & Mfg. Inc. A calibrated pressure sensor (McMaster-Carr part #3692N27) is used to monitor the imprint pressure at the sample. The imprint pressure is tuned by placing metallic shims of desired thickness around the guide rods of the die set to offset the pressing force that is experienced by the sample. The tool is enclosed in an environmentally isolated chamber for humidity monitoring and control. The humidity is controlled by pumping dry and moist air at a controlled rate, and/or by placing damp napkins within the chamber. The press is modified to enable automated activation of the pneumatic valve, where the control switch is placed outside the enclosed press. This ensures safe operation of the press, with the tool chamber closed before activation of the press.

### Nanocrystal Ink Formulation

A 15 wt % aqueous dispersion of anatase TiO₂ nanocrystals (NCs), ranging in diameter from 5 nm to 15 nm, is purchased from US Research Nanomaterials Inc. (stock #US7080) and used as the ink. The concentration of the ink is tailored by adding or evaporating a known mass of DI water to achieve 5-50 wt % inks. Viscosity of the NC dispersions is measured as a function of shear rate using a stress-controlled rheometer (DHR-3, TA Instruments) equipped with a 60 mm cone geometry.

### Si Master Mold Fabrication

A Si template, previously patterned using electron beam lithography, is comprised of a large patterned area (25 mm×25 mm) with 250 nm diameter circular nanopillars on a 400 nm pitch. This template is used to create a master mold on a Si wafer with a 250 nm or 500 nm thick oxide layer, depending on the desired template feature depth. A traditional nanoimprint lithography process with a Nanonex (NXR-1025) thermal resist is performed, where the resist is deposited by spin coating at 4000 rpm for 60 s and then soft baked at 155° C. for 3 min. The patterned Si template is placed on the surface of the resist, and placed in the Nanonex imprint tool, where the imprint is performed at 140° C. and 350 psi for 5 min. The template is separated from the imprinted resist sample, followed by an oxygen descum using an Oxford RIE etcher (40 mTorr pressure, 100 W power, and 20 sccm of O₂ for 30 s). A 50 nm thick Cr film is evaporated on the patterned and descummed resist, and a 3 min lift-off step in acetone is used to pattern the Cr layer. Plasma etch of the thermal oxide is performed with an Oxford RIE etcher with a Cr hard mask (e.g., 4 cycles at 40 mTorr pressure, 280 W power, 38 sccm Ar, and 12 sccm CHF3 for 30 s etches 150 nm of thermal oxide). Post etch, the Cr layer is removed by immersing the sample in a Transene Cr wet etchant, and the etched oxide features are silanized by exposing the features to an oxygen plasma and then immediately transferring the sample to a solution of octadecyltrichlorosilane (ODTS) in hexane. The mold is rinsed in hexane and dried.

### PDMS Mold Fabrication and Surface Treatment

The composite PDMS (cPDMS) template consists of a thin layer of hard PDMS (hPDMS) which is used to replicate the pattern of the Si master to limit pattern distortion during imprint, and a thick soft PDMS layer, for mechanical flexibility and handling. The hPDMS base and crosslinking agent (Sigma Aldrich) are mixed well in a 1:1 ratio and degassed at room temperature. The hPDMS is then spin-coated onto the silanized Si master and cured at 80° C. for 1.5 h. The soft PDMS base and crosslinking agent (Sigma Aldrich) are mixed in a 10:1 ratio and degassed at room temperature. A desired mass of soft PDMS is then poured onto the Si master to control the final thickness of the mold and cured at 75° C. for a minimum of 4 h. A level is used to ensure that the layer is flat during the curing step. The cured cPDMS template is gently peeled off the silane-coated Si mold and cut to the appropriate dimensions needed for imprint. To tailor the hydrophobicity of the templates, we treat the surface of the cPDMS template with UV ozone followed by overnight exposure to an ODTS saturated atmosphere in a vacuum bell jar.

### Spectral Characterization

Transmittance spectra are collected using a fiber optic UV/VIS spectrometer (Ocean Optics HDX-XR) with a Deuterium-Tungsten Halogen (Ocean Optics DH-2000 BAL) light source. Light is fed through a fiber optic cable to a collimating lens which creates a spot size of ˜2 mm at the sample. The light transmitted through the sample is collected by another fiber optic cable and collected by a back-thinned CCD image detector. The RI of the environment is modulated by adding solvents of varying RI onto the sample and recording the spectra.

### Ellipsometry and Fitting

Refractive index measurements are made using a J.A. Woollam V VASE Spectroscopic Ellipsometer, collected at four angles (45°, 55°, 65°, and 75°) and at wavelengths ranging from 400-1000 nm. Data sets are fit using a standard fitting protocol with a two-parameter Cauchy model on the J. A. Wollan CompleteEase software, for wavelengths in the visible where the TiO₂ film is transparent. MSE values of <5 is obtained for as imprinted films. Ligand-exchanged films as well as films treated by rapid thermal annealing at 350° C. are also measured, with typical MSE values <10.

### FDTD Simulation

FDTD (Lumerical) simulations are used to simulate the optical response of the TiO₂ NC metasurface. All simulations are carried out on a glass substrate (n=1.45). A mesh size of 5 nm is used inside of the TiO₂ region of the simulation. The dielectric function of the bulk TiO₂layer is obtained from MTI Corporation. The TiO₂ NC dielectric function is directly measured using ellipsometry and imported into the FDTD software.

### Direct Nanocrystal Imprint Process

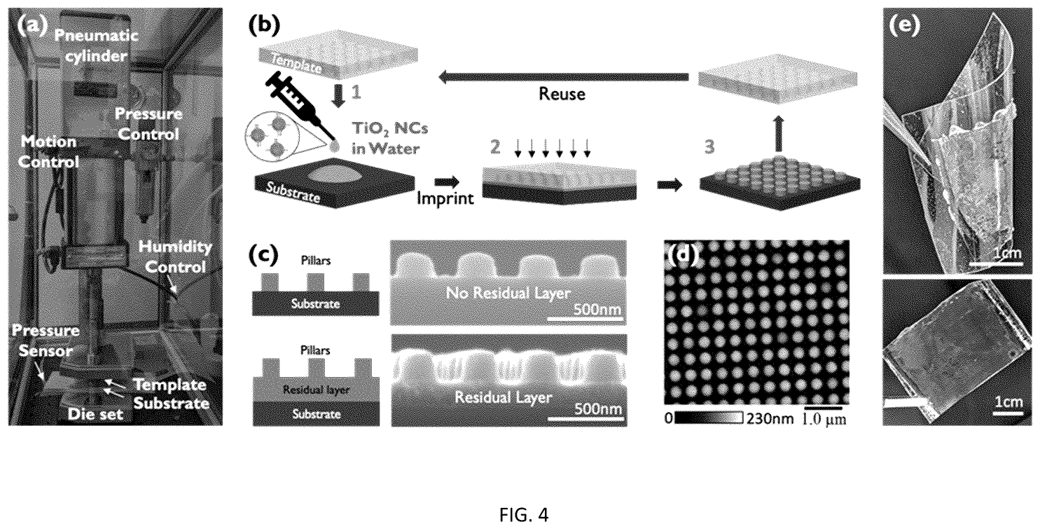

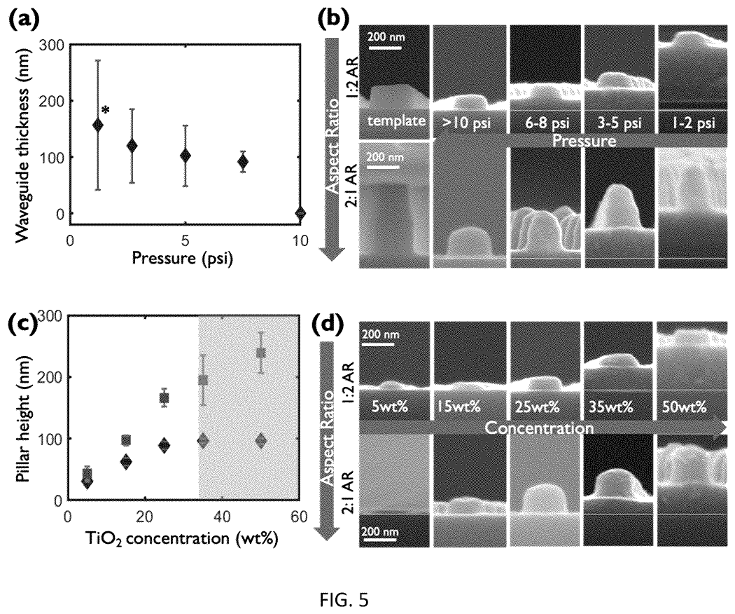

We report a nanoimprint process to transfer patterns from polymeric templates with recessed features into aqueous NC dispersions. We build a custom imprint tool by mounting a benchtop pneumatic arbor press and a die set in an environmentally isolated enclosure (FIG. 4a). Pressure, temperature, and humidity sensors and actuators are integrated into the tool to measure and control imprint pressure, chamber humidity, and pressing speed. Metallic shims between the top and base of the die set tune the effective pressure transmitted from the press to the sample while retaining the planarity of the die set necessary to obtain uniform imprints. Imprint pressure is electronically controlled using a pneumatic valve connected to house air supply, with an operating range of 20-80 psi. Pressure at the sample is monitored using a flexible, flat, resistive pressure sensor whose transfer function is characterized using standard weights and a multimeter. The sensor is attached to the underside of an aluminum baseplate on the base of the die set to ensure that the sensor topography does not affect imprint uniformity. A wide range of effective pressures at the sample, from 0-100 psi, are obtained by precisely controlling the contact between the template and substrate during the imprint process.

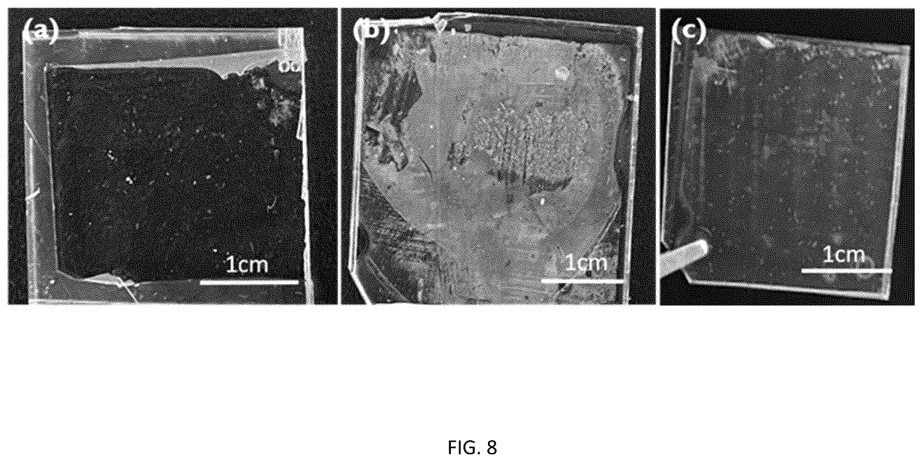

Composite polydimethylsiloxane (cPDMS) templates, composed of a hard PDMS (hPDMS) film supported by a soft PDMS layer, are fabricated from silane-coated, Si molds comprised of desired nanopatterns, where the Si mold is made by traditional CMOS fabrication. PDMS is chosen for its flexibility and water permeability which enables the use of water-based inks in the imprint process. Silanization of the cPDMS templates ensures their reusability (FIGS. 8a-8c). 15 wt % aqueous TiO₂ NC dispersions are used as-is, or a known weight of the solvent (i.e., of water) is added or evaporated to vary the NC concentration from 5 wt % to 50 wt %. In a typical imprint process, the NC dispersion is pipetted onto the target substrate, the template is place manually atop the NC dispersion, and the template-substrate assembly with a wet NC layer is placed on the baseplate. The pneumatic valve is turned on to press the top die set on the template-substrate assembly (FIG. 8b). Alternatively, the template can be attached to the top of the die set, and the NC dispersion drop-cast on the substrate. Similar imprint results are obtained with either method of template placement. The speed of template approach can be controlled by adjusting motion control knobs on the pneumatic press. During the pressurized imprint, water from the ink diffuses through the cPDMS and exposed edges of the template. After the ink is dry, the pneumatic valve is turned off, retracting the top die set. The template is separated from the substrate either during the retraction, or by gently peeling it off the substrate, yielding a patterned substrate.

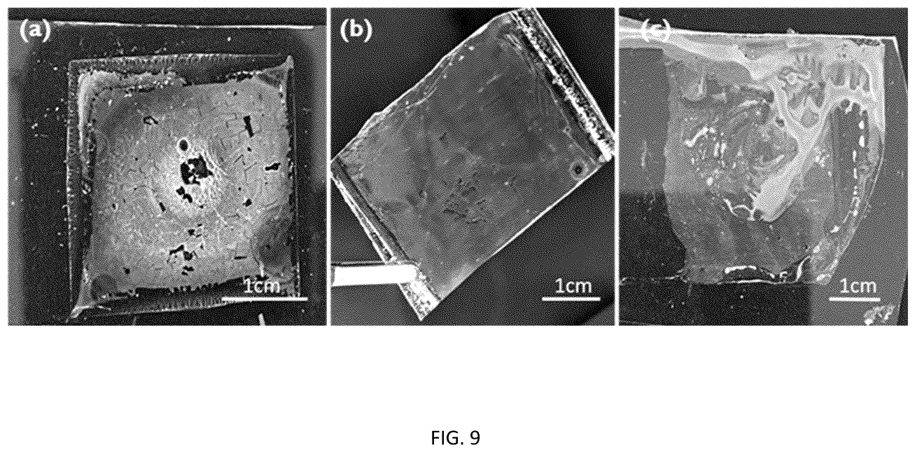

Relative humidity (RH) in the tool chamber plays a role in print quality and process time. If the RH is low, the time required for the ink to dry decreases, but TiO₂ NC aggregates are seen to form, causing pillar breakage and delamination from the substrate. High humidity enables good print quality, however, >50% RH decreases the water evaporation rate causing a substantial increase in the required printing time. An optimal humidity range for reliable prints is found to be between 25% and 40% RH (FIG. 9) for a typical print time of 2 h for a 15 mm×15 mm template, to allow for evaporation of water in the ink.

Using this custom imprint tool and process, we achieve large area (>625 mm²) prints on rigid and flexible polymeric substrates (FIGS. 4c-4e). The resulting imprinted nanostructures are characterized using AFM and cross-sectional SEM imaging to measure pillar height and residual NC layer thickness. Imprint process parameters are tuned to achieve nanopillar heights from 30 nm-250 nm and residual layer thicknesses (RLT) from 0 nm-1 μM.

### Parameter Space for Reliable Nanoimprints

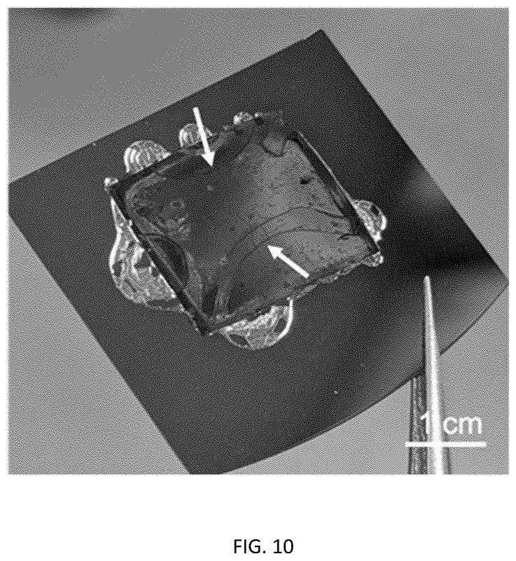

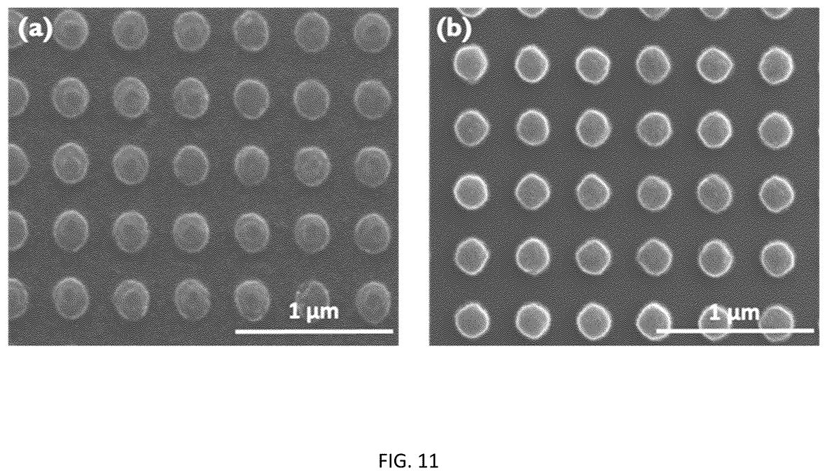

FIG. 5 shows the effect of imprint process parameters on the final imprinted TiO₂ NC pillars. cPDMS templates are made from Si molds comprised of 250±4 nm diameter circular pillars with 140±10 nm heights (and thus a 1:2 aspect ratio (AR)) and with 450±5 nm heights (2:1 AR), in which the pillars are arrayed on square lattices with 400 nm pitches. Imprint pressure is tailored from 0-40 psi with a fixed, 25 wt % aqueous TiO₂ NC concentration. Imprints at pressures >40 psi result in extreme deformation of the cPDMS templates and cracking of the hPDMS layer (FIG. 10). We observe imprinted pillars with heights of 88±10 nm for the 1:2 AR template, and 230±25 nm for 2:1 AR template for all pressures (0-80 psi), smaller than the template feature depth due to water evaporation from the ink (FIG. 5b). Residual NC layers are seen below the pillars for imprint pressures <10 psi. The residual layer thickness (RLT) is inversely correlated with imprint pressure (FIG. 5a). At the lowest pressures, the thickness of the residual layer is non-uniform, and 0-2 psi imprints result in material delamination from the substrate. Higher pressures improve residual layer uniformity, with a RLT of 92 nm±20% for 7.5 psi pressure imprints. FIG. 11 shows top-down SEMs of imprinted samples with and without a residual layer resulting from imprinting at low and high pressures, respectively. Thus, the pressure can be used tune the RLT.

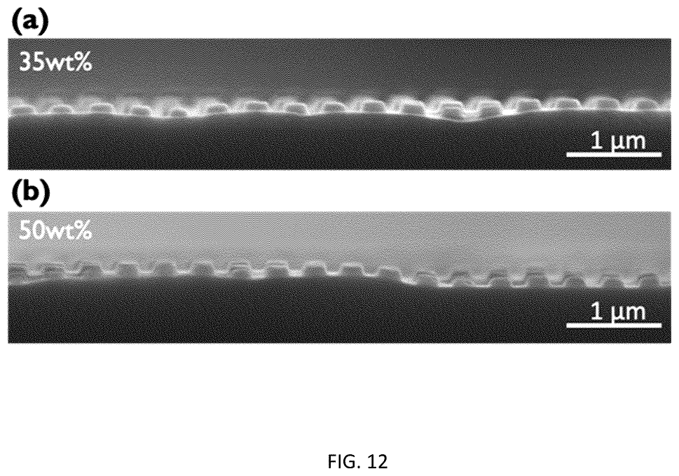

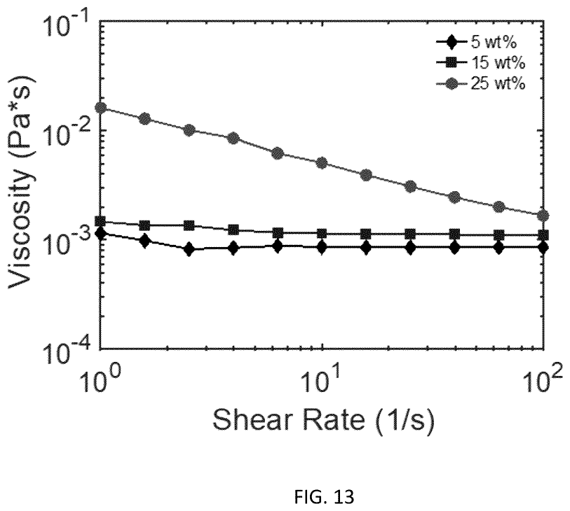

The effect of NC concentration on imprint geometry is quantified by varying the concentration from 5-50 wt % at a fixed imprint pressure of 10 psi. FIGS. 5c and 5d show that nanopillar height increases with an increase in NC concentration. Low ink concentrations result in shorter pillars due to the higher volumes of water, while higher concentrations yield pillars of a maximum height of ˜60% of template feature depth. NC dispersions of 5 wt % to 25 wt % are translucent and show uniform, large area imprints. In concentrating the NC dispersions to 35 wt % and 50 wt %, particles are seen to sediment and require agitation, forming milky white inks that do not spread well when deposited on the substrate, resulting in a nonuniform layer below the pillars (FIG. 12). Viscosity measurements of the 5 wt % and 15 wt % NC dispersions show relatively low (water-like) viscosity and Newtonian behavior, however measurements of 25 wt % NC dispersions exhibit higher viscosity at low shear-rates consistent with particle agglomeration (FIG. 13) and shear-thinning behavior. Thus, we control pillar height and RLT of imprinted structures by modifying NC concentration and imprint pressure for a given template.

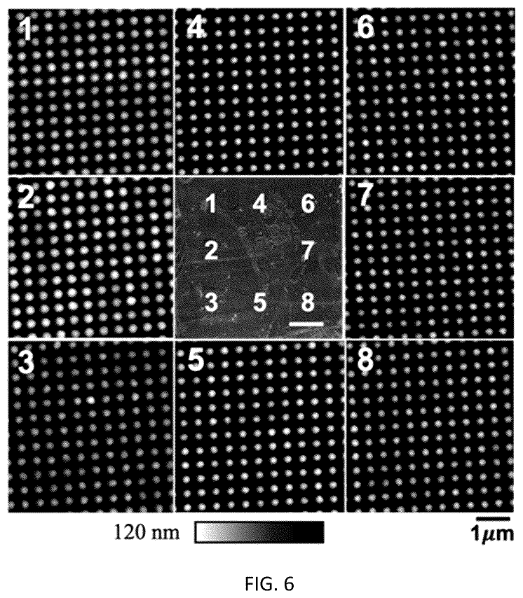

To demonstrate the large-area uniformity and scalability of this process, we imprint a 25 mm×25 mm template with 25 wt % NC inks at a pressure of 10 psi. AFM images are collected at eight different regions across the imprinted TiO₂ NC metasurface (FIG. 6). Line cuts are taken across each AFM image to characterize the heights of ˜80 pillars across the eight different scanned regions, yielding an average pillar height of 95.2±9.4 nm.

### Optical Characterization

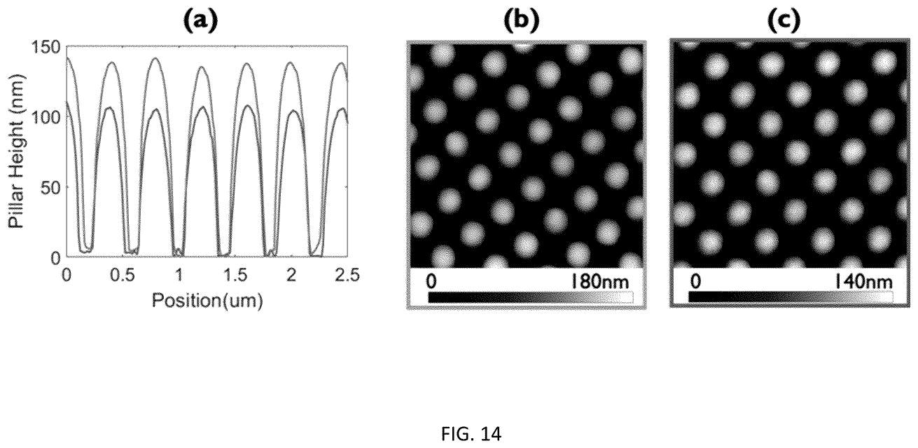

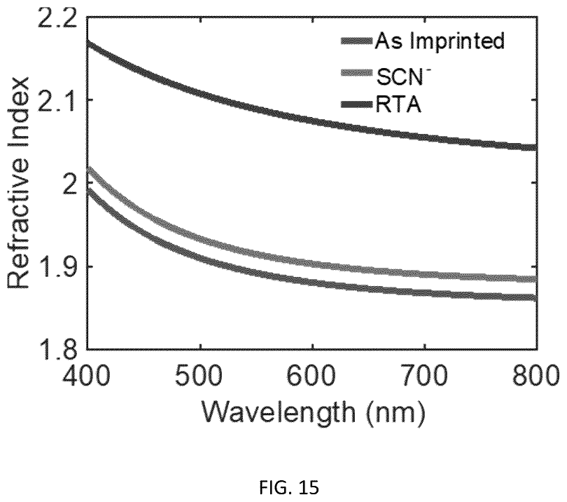

The RI of uniform blank TiO₂ NC films, fabricated by imprinting with an unpatterned template and a 25 wt % TiO₂ NC ink, is measured using ellipsometry. To improve the RI, room temperature ligand exchange using NH₄SCN is carried out. AFM measurements of patterned pillars show that ligand exchange densities and shrinks by 30% the NC structures (FIG. 14). A RI of 1.94±0.02 at 543 nm wavelength is obtained using our water-based direct NC imprint process (FIG. 15). In contrast, sol-gel and resin-based TiO₂ NC inks obtain a similar RI value only after high temperature and/or UV anneals (Table 1).

TABLE 1
Direct patterning of TiO₂ metasurfaces

| | Ink | Imprint | | RI |
|---|---|---|---|---|
| Ink Composition | Application | Method | Annealing | (Wavelength) |
| TiCl₄, Pluronic F127 | Dip coat | Thermal NIL | 350° C. | 2.18 (600 nm) |
| (polyethylene oxide- | | | | |
| polypropylene oxide triblock | | | | |
| copolymer), EtOH, water | | | | |
| TiO₂ NPs, MIBK, monomer | Drop cast | Pressure and | UV to cure | 1.94 (532 nm) |
| mixture, photoinitiator | | UV NIL | | |
| TiO₂ NCs, small molecule sol-gel, | Spin coat | UV NIL | UV cycling to cure | 1.95 (543 nm) |
| Anionic surfactant, ethyl | | | ALD of TiO₂ | 2.15 (543 nm) |
| acetate, silane coupling agent | | | | |
| TiO₂ NCs, Water | Drop cast | Pressure NIL | None | 1.89 (543 nm) |
| | | | NH₄SCN LE | 1.94 (543 nm) |
| | | | 350° C. | 2.09 (543 nm) |

The RI of our NC layers is sufficient to support guided mode resonances that can couple to an overlaying pillar array to support quasi-guided modes (QGMs). Further, RI of >2 can be obtained with our films using a thermal anneal at 350° C. for 60 min, similar to post-anneal RI values obtained in other works as shown in Table 1.

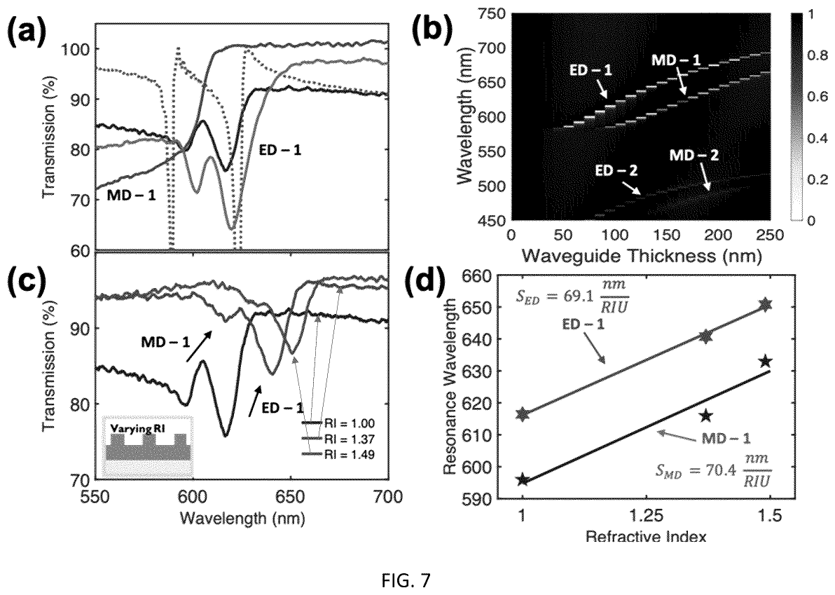

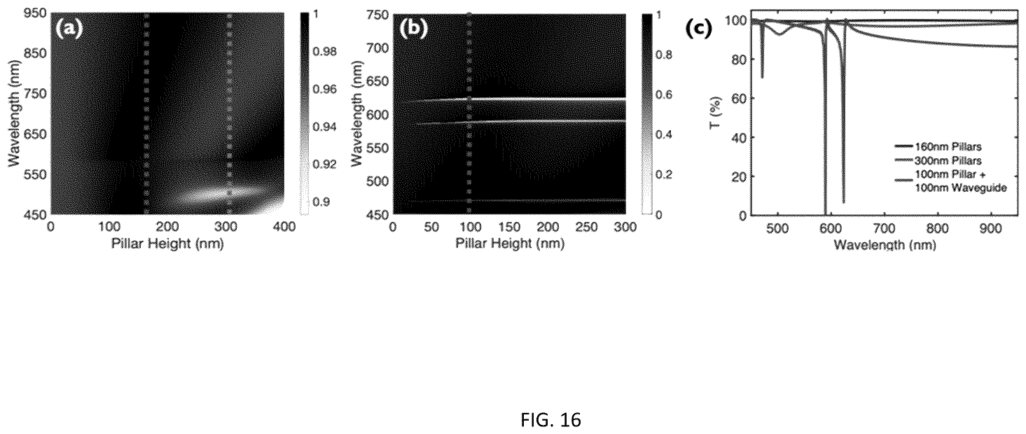

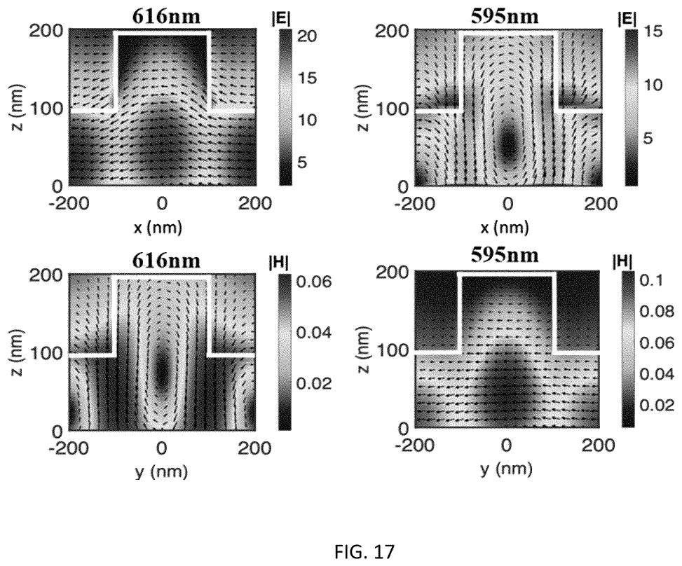

Dielectric metasurfaces composed of TiO₂ NC pillars with and without a residual NC waveguide layer are achieved in a single patterning step by tailoring the nanoimprinting pressure and NC ink concentration. Mie resonances of the NC pillar arrays are not observed (FIG. 7a) as the TiO₂ NC optical path length, i.e., the product of the RI and pillar height, is too low (FIG. 16a). The pillar spectra have a ˜20% decrease in transmitted light at ˜600 nm which corresponds to the first order Rayleigh-Woods anomaly. FIG. 7a shows QGM resonances for 100 nm and 150 nm pillars printed with residual layers acting as waveguides. Both QGM spectra show first-order magnetic dipole resonances (MD-1) at 598 nm and a higher intensity first-order electric dipole (ED-1) resonance at 618 nm, consistent with simulations. The overlapping spectral positions of the dipole resonances indicate that their residual layers are of similar thickness. Consequently, the increased modulation observed for the 150 nm pillars is due to the increased optical thickness. Simulated electric and magnetic field maps support the origin of these resonances (FIG. 17). FIG. 7b shows that a waveguide thickness of ˜100 nm supported the ED and MD resonances, achievable at low imprint pressures ranging from 3-8 psi with 25 wt % NC inks, as seen in FIG. 5c.

The spectral position of the MD and ED resonances are very sensitive to the guided mode resonances which strongly depend on the NC waveguide thickness (FIG. 7b). Below 40 nm, the optical thickness of the waveguide is too small to support the first order guided modes needed for the ED-1 and MD-1 resonances. As the thickness of the waveguide increases, the associated wavevector k=2 π/λ decreases allowing for longer wavelength guided mode resonances to be supported. This results in a redshift of the supported ED-1 and MD-1 resonances as the waveguide thickness increases. For waveguide thicknesses >150 nm, lower intensity peaks can be observed around a wavelength of 460 nm. These modes are spectrally close to the substrate Rayleigh-Woods anomaly which is calculated to resonate at 430 nm. This suggests that these peaks (labeled ED-2 and MD-2) are higher order modes of the QGMs coupled to a higher order RA. Pillar height has a negligible effect on the spectral position of the QGM resonances, while the presence of a waveguide is necessary for strong resonances (FIGS. 15b-15c).

The environment RI has a strong influence on the spectral characteristics of the QGM resonances, motivating the use of these metasurfaces as RI sensors. The environment RI is tuned from 1.00 (air) to 1.49 (toluene) by depositing various solvents on the sample surface (FIG. 7c). The MD-1 and ED-1 resonances red shift by 36.9 nm and 34.3 nm, respectively. Furthermore, the ED-1 peak exhibits a 6% reduction in intensity while the MD-1 peak is almost completely annihilated when the RI of the environment increases to 1.49. This is a result of a reduction in the RI contrast between the environment and the waveguide causing light leakage at the interface between the waveguide and the environment.

$$70.4 \frac{nm}{RIU} and 69.1 \frac{nm}{RIU} ,$$

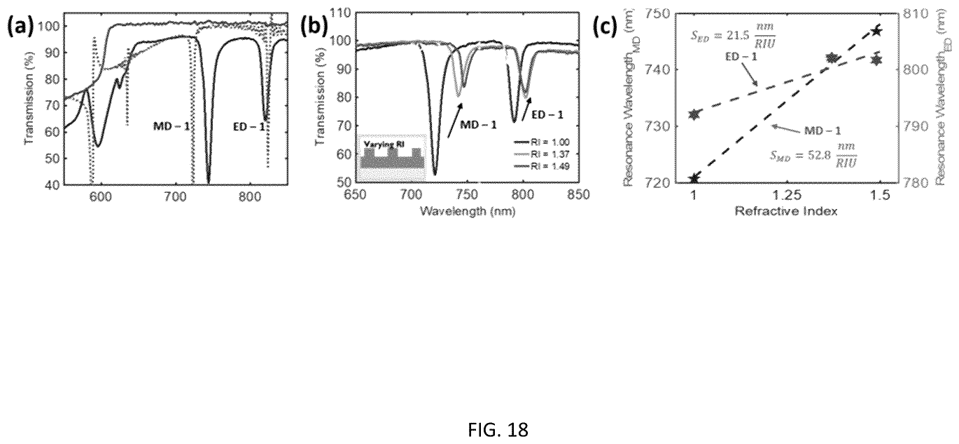

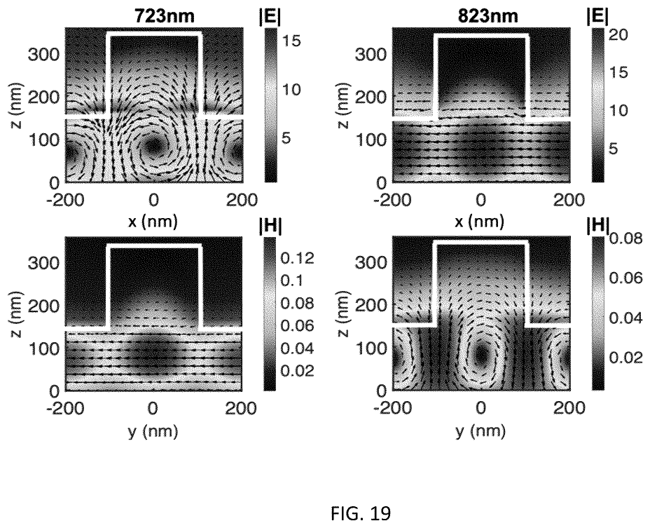

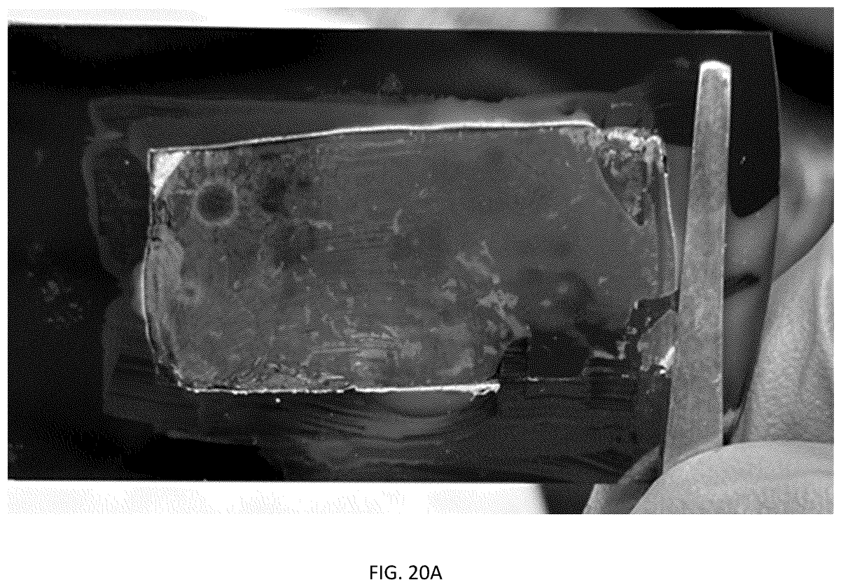

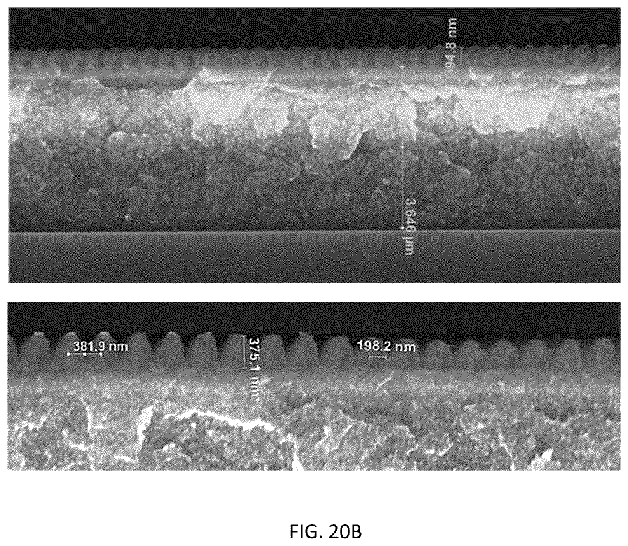

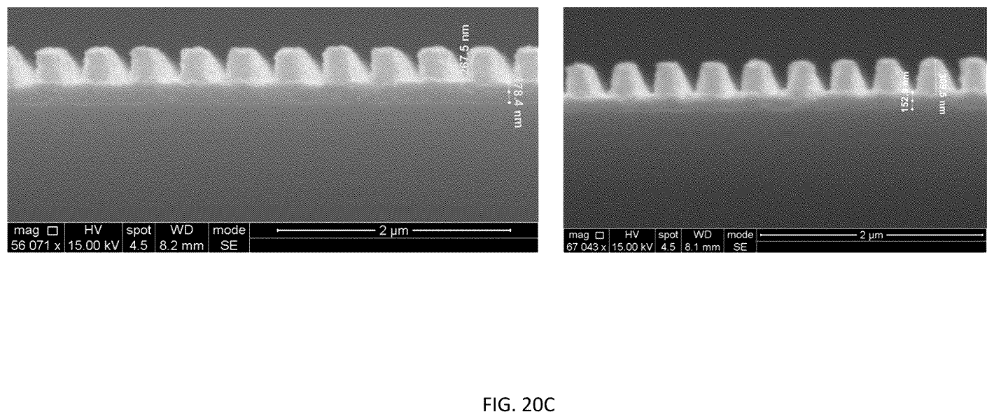

The sensitivities (S) of the MD-1 and ED-1 resonances are respectively (FIG. 7d). These sensitivities are higher than those observed experimentally and simulated for a bulk TiO₂ waveguide case (FIG. 18). This contrast can be explained by the cross-sectional electric and magnetic field maps for both structures (FIGS. 18-19). The fields generated are weakly (strongly) confined within the NC (bulk) waveguide due to its lower (higher) RI which causes strong (weak) environmental interaction, increasing (decreasing) their sensitivities. This results in a tradeoff between peak intensity and RI sensitivity. The bulk waveguide can sustain both modes at higher environmental RIs at the cost of sensitivity, whereas the NC waveguide is not able to sustain the modes at high environmental RIs but they exhibit high RI sensitivities. The ED-1 and MD-1 peaks show the expected strong linear dependence on the environment RI, and the peak positions are recovered when the RI is cycled (FIG. 7d). The sensing capability is evaluated by calculating the FOM=Q×S. The ED-1 and MD-1 resonances exhibit high FOMs of 4082 and 3326, respectively, which motivates the use of these sustainably fabricated metasurfaces for sensing applications.

### Conclusion

Dielectric metasurfaces are fabricated at room temperature using soft-nanoimprint lithography with aqueous TiO₂ NC inks free of polymeric additives. The geometry of the printed metasurfaces is tuned by varying imprint parameters such as pressure and ink concentration to fabricate pillars with and without a residual layer. The presence of the residual layer, which acts as a waveguide, is essential to excite QGM resonances for high FOM sensing, obviating the need for high aspect ratio NC nanopillars which may suffer from feature collapse and patterning challenges. The aqueous inks used and the dense films that are printed eliminate the need for environmentally harmful chemicals and high temperature anneals that are typically used in resin-based and sol-gel based processes. This work serves as the foundation for scalable, environmentally benign and sustainable manufacturing of rigid or flexible optical devices that require patterned subwavelength structures. This process is promising for markets which require low-cost manufacturing of devices on unconventional substrates such as polymeric substrates, which are of interest for sensing, wearable devices, and flexible lens applications.

This process can be extended to the wider NC library. For example, many aqueous dispersions of metal oxide, semiconductor, and plasmonic NCs are routinely synthesized. Consequently, metasurfaces made of mixtures of nanocrystalline materials and arbitrarily complex material systems can be fabricated without the need for polymer additives. The nanocrystalline nature of the printed structures allows for an additional control knob as the NC spacing and by extension, film densities can be tuned via room temperature ligand exchange processes. The optical resonances that are excited by these NC metasurfaces have high sensitivities to their environmental RI and their relative intensities can be modulated. This process can also be extended to complex structures that can enable unique optical phenomena such as printing chiral structures to unlock and control additional optical degrees of freedom. One can use these resonances in applications where high sensitivities to changes in environmental RI are useful and where the resonances can be switched between on and off states, such as in flexible optofluidic displays, biosensors, and tunable flat optics.

### Aspects

The following Aspects are illustrative only and do not limit the scope of the present disclosure or the appended claims. It should be understood that any part or parts of any Aspect can be combined with any part or parts of any other Aspect.

Aspect 1. A nanostructure imprinting process, comprising: contacting a template stamp to an amount of a dispersion disposed on a surface, the template stamp having a pattern thereon, the dispersion comprising an aqueous solvent having a plurality of nanoparticles dispersed therein, the nanoparticles optionally having a diameter of from about 2 nm to about 1000 nm, and the contacting being performed such that the dispersion at least partially fills the pattern of the template stamp; and effecting at least partial removal of the aqueous solvent so as to give rise to structures that comprise the nanoparticles and that substantially conform to the pattern of the template stamp, the structures optionally defining a metasurface.

Aspect 2. The process of Aspect 1, further comprising maintaining the template stamp in position while effecting removal of the solvent.

Aspect 3. The process of any one of Aspects 1-2, wherein the structures contact the surface.

Aspect 4. The process of any one of Aspects 1-3, wherein a structure defines a characteristic dimension in the range of from about 5 nm to about 1000 nm.

Aspect 5. The process of any one of Aspects 1-4, wherein the dispersion infiltrates into the pattern of the template stamp.

Aspect 6. The process of any one of Aspects 1-5, wherein the imprinting process results in a stable structure with no residual layer of nanoparticles.

Aspect 7. The process of any one of Aspects 1-6, wherein the imprinting process results in a stable structure with a residual film comprising the nanoparticles beneath the structures, the residual film having a thickness of from about 5 nm to about 25 μm.

Aspect 8. The process of any one of Aspects 1-7, wherein the nanoparticles comprise any one or more of a metal, a metal oxide, a semiconductor, an insulator, or any combination thereof.

Aspect 9. The process of any one of Aspects 1-8, wherein the nanoparticles are crystalline.

Aspect 10. The process of any one of Aspects 1-8, wherein the nanoparticles are amorphous.

Aspect 11. The process of any one of Aspects 1-10, wherein the nanoparticles comprise at least one of rutile TiO₂ and anatase TiO₂.

Aspect 12. The process of any one of Aspects 1-11, wherein the nanoparticles comprise one or more ligands present thereon.

Aspect 13. The process of Aspect 12, wherein a ligand comprises any one or more of polyvinylpyrrolidone (PVP), polyethylene glycol (PEG), polystyrene (PS), oleic acid (OA), oleylamine (OAm), Amines (RNH₂), phosphines (R₃P), phosphine oxides (R₃PO), carboxylic acid, carboxylates (RCOO⁻), thiolates (RS⁻), phosphonates (RPO(OH)O⁻), inorganic ions (such as Cl⁻, InCl₄⁻, AsS3³⁻), ammonium thiocyanate (NH₄SCN), zwitterionic (ZW) ligands, chalcogenidometallates (for example Sn₂S₆⁴⁻, In₂Se₄²⁻, CdTe₂²⁻), halometallates (PbCl₃⁻, InCl₄⁻), chalcogenide (S²⁻), halide (Cl⁻, I⁻) and pseudohalide (SCN⁻, N₃⁻) ions, citrates, or an OH-terminated ligand. The foregoing examples are illustrative only and are not exclusive. One can have a mix of ligands for which the particles would be ultimately dispersible. Without being bound to any particular theory or embodiment, one can also, e.g., have an amine on one side and a carboxylic acid on the other and then be dispersible—where the amine would bind to the particle surface and the —COOH would extend into the solvent.

Aspect 14. The process of any one of Aspects 12-13, further comprising any one or more of exchanging the ligands of the nanoparticles and removing the ligands of the nanoparticles.

Aspect 15. The process of Aspect 14, wherein the ligand exchange or removal is performed so as to adjust an optical property of the metasurface.

Aspect 16. The process of any one of Aspects 1-15, wherein the template stamp comprises at least one of glass, silicon, nickel, and PDMS.

Aspect 17. The process of any one of Aspects 1-16, wherein the dispersion further comprises a further component.

Aspect 18. The process of Aspect 17, wherein the further component comprises a polar solvent or a non-polar solvent. Example further components include, e.g., methanol, ethanol, NMP, N-methylformamide, formamide, dimethylsulphoxide, acetone, ethylamine, tetrahydrofuan, isopropanol, and the like. Without being bound to any particular theory or embodiment, solvents, including THF and solvents with a relatively small aliphatic group bound to a —OH (e.g., methanol, ethanol, and isopropanol) can be useful. A surfactant can also be present in the dispersion.

Aspect 19. The process of Aspect 17, wherein the further component comprises a polymer.

Aspect 20. The process of any one of Aspects 1-19, wherein removal of the aqueous solvent comprises application of any one or more of an adjusted pressure, an adjusted humidity and/or an adjusted temperature. As an example, removal of the aqueous solvent can be effected by application of one or more of a reduced humidity, a reduced pressure, and an increased temperature.

Aspect 21. The process of any one of Aspects 1-20, wherein the dispersion comprises up to about 60 wt % nanoparticles. Without being bound to any particular theory or embodiment, a dispersion can include up to about 60 wt % nanoparticles, up to about 55 wt % nanoparticles, up to about 50 wt % nanoparticles, up to about 45 wt % nanoparticles, up to about 40 wt % nanoparticles, up to about 35 wt % nanoparticles, up to about 30 wt % nanoparticles, up to about 25 wt % nanoparticles, up to about 20 wt % nanoparticles, up to about 15 wt % nanoparticles, up to about 10 wt % nanoparticles, up to about 5 wt % nanoparticles, or even up to about 2 wt % nanoparticles. A dispersion can have from about 2 to about 60 wt % nanoparticles, from about 5 to about 53 wt % nanoparticles, from about 9 to about 47 wt % nanoparticles, from about 13 to about 43 wt % nanoparticles, from about 17 to about 43 wt % nanoparticles, from about 22 to about 39 wt % nanoparticles, or from about 25 to about 35 wt % nanoparticles.

Aspect 22. The process of any one of Aspects 1-21, wherein the surface is substantially planar surface, the substantially planar surface optionally being a surface of a wafer.

Aspect 23. The process of any one of Aspects 1-21, wherein the structure is a three-dimensional structure, the three-dimensional structure optionally defining a pillar.

Aspect 24. The process of any one of Aspects 1-23, further comprising any one or more of exchanging ligands present on the structures, thermally annealing the structures, and compacting the structures.

Aspect 25. The process of any one of Aspects 1-24, further comprising dispensing the amount of dispersion onto the surface.

Aspect 26. The process of any one of Aspects 1-25, wherein the process is performed in a continuous manner, the continuous manner optionally being a roll-to-roll process. Such processes can be performed on a continuous substrate or on discrete or separate substrates.

Aspect 27. The process of any one of Aspects 1-26, wherein the process is performed at or below about 80° C. Without being bound to any particular theory or embodiment, one can apply the disclosed technology to processes that incorporate substrates that do not easily tolerate higher processing temperatures. For example, paper, polymers, and the like can be used with the disclosed technology.

Aspect 28. A structure, the structure made according to any one of Aspects 1-27.

Aspect 29. A system, comprising: an amount of a dispersion comprising an aqueous solvent having a plurality of nanoparticles dispersed therein, the nanoparticles optionally having a diameter of from about 2 nm to about 1000 nm; a template stamp having a pattern thereon; a surface; and an applicator, the applicator configured to dispense an amount of the dispersion onto the surface, the system being configured to contact the template stamp to dispensed dispersion so as to give rise to structures that comprise the nanoparticles and substantially conform to the pattern of the template stamp.

Aspect 30. A metasurface, comprising a substrate; and a plurality of structures superposed on the substrate, a structure comprising a plurality of nanoparticles associated together, a structure having a characteristic dimension in the range of from about 5 nm to about 1000 nm.

Aspect 31. The metasurface of Aspect 30, wherein the structures are associated with an optical property of the metasurface, and comprise pillars, holes, or both.

Aspect 32. The metasurface of Aspect 31, wherein the pillars are any one or more of circular in cross-section, bowtie in cross-section, polygonal in cross-section, or asymmetric in cross section.

Aspect 33. The metasurface of Aspect 32, wherein the pillars are substantially circular in cross-section.

Aspect 34. The metasurface of any one of Aspects 30-33, wherein the substrate comprises a polymer.

Aspect 35. The metasurface of any one of Aspects 30-34, wherein the structures are dielectric materials.

Aspect 36. The metasurface of any one of Aspects 30-35, wherein the metasurface is configured to reflect light in any one or more of a visible range or an infrared range, the infrared range optionally being short wavelength infrared.

Aspect 37. The metasurface of Aspect 36, wherein the metasurface is configured to reflect light in a visible range response to a physical change of the substrate.

Aspect 38. The metasurface of any one of Aspects 33-37, wherein the metasurface is integrated in a sensor component or sensor system.

Aspect 39. The metasurface of any one of Aspects 33-38, further comprising a residual film comprising the nanoparticles, the residual film disposed between the structures and the substrate.

Aspect 40. A nanostructure imprinting process, comprising: contacting a template stamp to an amount of a dispersion disposed on a surface, the template stamp having a pattern thereon, the dispersion (i) comprising a temperature-thinning solvent and (ii) having a plurality of nanoparticles dispersed therein, the nanoparticles optionally having a diameter of from about 2 nm to about 1000 nm, and the contacting being performed such that the dispersion at least partially fills the pattern of the template stamp; and effecting at least partial removal of the solvent so as to give rise to structures that comprise the nanoparticles and that substantially conform to the pattern of the template stamp, the structures optionally defining a metasurface.

Aspect 41. The nanostructure imprinting process of Aspect 40, wherein the temperature-thinning solvent comprises any one or more of terpineol or cresol, and further wherein the dispersion optionally comprises TiO₂ nanoparticles.

Aspect 42. The nanostructure imprinting process of Aspect 40, wherein the temperature-thinning solvent has a viscosity of greater than 2 centipoise at temperatures below about 20° C.

Aspect 43. The nanostructure imprinting process of Aspect 40, wherein the temperature-thinning solvent has a viscosity of about 0.1 cP to about 50 cP at between 40 and 80° C.

Aspect 44. The nanostructure imprinting process of Aspect 40, wherein the dispersion has a viscosity of from about 2 cP to about 100,000 cP at temperatures below 50° C. For example, the dispersion can have a viscosity of from about 2 cP to about 100,000 cP at 20° C., or from about 5 cP to about 50,000 cP at 20° C., or from about 10 cP to about 1000 cP at 20° C., or even from about 50 cP to about 500 cP at 20° C.

Aspect 45. The nanostructure imprinting process of Aspect 40, wherein the temperature-thinning solvent has a viscosity at room temperature of greater than 2 centipoise and less than about 100,000 cP, One can select the temperature-thinning solvent such that the solvent has a viscosity of less than about 2 cP at 20° C. (room temperature). One can also select the solvent and the nanoparticle loading such that the dispersion has a viscosity of less than or equal to about 2 cP at 20° C.

Aspect 46. The process of any one of Aspects 40-45, further comprising maintaining the template stamp in position while effecting removal of the solvent. One can also maintain the template stamp in position while changing the ambient temperature. For example, the stamp can be maintained in position while the ambient temperature is increased. For example, the stamp can be maintained in position while the ambient temperature is decreased.

Aspect 47. The process of any one of Aspects 40-46, wherein the structures contact the surface.

Aspect 48. The process of any one of Aspects 40-47, wherein a structure defines a characteristic dimension in the range of from about 5 nm to about 1000 nm. This dimension can be a height, for example, the height of a pillar. The dimension can be, for example, from about 5 nm to about 1000 nm, from about 10 nm to about 750 nm, from about 20 nm to about 500 nm, or even from about 50 nm to about 250 nm.

Aspect 49. The process of any one of Aspects 40-48, wherein the imprinting process results in a structure (which structure can be stable) with no residual layer of nanoparticles. Thus, the structure can be formed directly on the surface, free of a residual layer beneath.

Aspect 50. The process of any one of Aspects 40-48, wherein the imprinting process results in a stable structure with a residual film comprising the nanoparticles beneath the structures, the residual film having a thickness of from about 5 nm to about 25 mn.

Aspect 51. The process of any one of Aspects 40-49, wherein the nanoparticles comprise any one or more of a metal, a metal oxide, a semiconductor, an insulator, or any combination thereof.

Aspect 52. The process of any one of Aspects 40-49, wherein the nanoparticles are crystalline.

Aspect 53. The process of any one of Aspects 40-52, wherein the nanoparticles are amorphous.

Aspect 54. The process of any one of Aspects 40-53, wherein the nanoparticles comprise at least one of rutile TiO₂ and anatase TiO₂.

Aspect 55. The process of any one of Aspects 40-54, wherein the nanoparticles comprise one or more ligands present thereon.

Aspect 56. The process of any one of Aspects 40-55, further comprising any one or more of exchanging the ligands of the nanoparticles and removing the ligands of the nanoparticles.

Aspect 57. The process of Aspect 56, wherein the ligand exchange or removal is performed so as to adjust an optical property of the metasurface.

What is claimed:

1. A nanostructure imprinting process, comprising:
contacting a template stamp to an amount of a dispersion disposed on a surface,
the template stamp having a pattern thereon,
the dispersion comprising an aqueous solvent having a plurality of nanoparticles dispersed therein, the nanoparticles optionally having a diameter of from about 2 nm to about 1000 nm, and
the contacting being performed such that the dispersion at least partially fills the pattern of the template stamp; and
effecting at least partial removal of the aqueous solvent so as to give rise to structures that comprise the nanoparticles and that substantially conform to the pattern of the template stamp,
the structures optionally defining a metasurface.

2. The process of claim 1, further comprising maintaining the template stamp in position while effecting removal of the solvent.

3. The process of claim 1, wherein the structures contact the surface.

4. The process of claim 1, wherein a structure defines a characteristic dimension in the range of from about 5 nm to about 1000 nm.

5. The process of claim 1, wherein the dispersion infiltrates into the pattern of the template stamp.

6. The process of claim 1, wherein the imprinting process results in a stable structure with no residual layer of nanoparticles.

7. The process of claim 1, wherein the imprinting process results in a stable structure with a residual film comprising the nanoparticles beneath the structures, the residual film having a thickness of from about 5 nm to about 25 μm.

8. The process of claim 1, wherein the nanoparticles comprise any one or more of a metal, a metal oxide, a semiconductor, an insulator, or any combination thereof

9. The process of claim 1, wherein the nanoparticles are crystalline.

10. The process of claim 1, wherein the nanoparticles are amorphous.

11. The process of claim 1, wherein the nanoparticles comprise at least one of rutile TiO₂ and anatase TiO₂.

12. The process of claim 1, wherein the nanoparticles comprise one or more ligands present thereon.

13. The process of claim 12, wherein a ligand comprises any one or more of polyvinylpyrrolidone (PVP), polyethylene glycol (PEG), polystyrene (PS), oleic acid (OA), oleylamine (OAm), Amines (RNH₂), phosphines (R₃P), phosphine oxides (R₃PO), carboxylic acid, carboxylates (RCOO⁻), thiolates (RS⁻), phosphonates (RPO(OH)O⁻), inorganic ions (such as Cl⁻, InCl₄⁻, AsS3³⁻), ammonium thiocyanate (NH₄SCN), zwitterionic (ZW) ligands, chalcogenidometallates (for example Sn₂S₆⁴⁻, In₂Se₄²⁻, CdTe₂²⁻), halometallates (PbCl₃⁻, InCl₄⁻), chalcogenide (S²⁻), halide (Cl⁻, I⁻) and pseudohalide (SCN⁻, N₃⁻) ions, citrates, or an OH-terminated ligand.

14. The process of claim 12, further comprising any one or more of exchanging the ligands of the nanoparticles and removing the ligands of the nanoparticles.

15. The process of claim 14, wherein the ligand exchange or removal is performed so as to adjust an optical property of the metasurface.

16. The process of claim 1, wherein the template stamp comprises at least one of glass, silicon, nickel, and PDMS.

17. The process of claim 1, wherein the dispersion further comprises a further component.

18. The process of claim 17, wherein the further component comprises a polar solvent or a non-polar solvent.

19. The process of claim 17, wherein the further component comprises a polymer.

20. The process of claim 1, wherein removal of the aqueous solvent comprises application of any one or more of an adjusted pressure, an adjusted humidity and/or an adjusted temperature.

21. The process of claim 1, wherein the dispersion comprises up to about 60 wt % nanoparticles.

22. The process of claim 1, wherein the surface is substantially planar surface, the substantially planar surface optionally being a surface of a wafer.

23. The process of claim 1, wherein the structure is a three-dimensional structure, the three-dimensional structure optionally defining a pillar.

24. The process of claim 1, further comprising any one or more of exchanging ligands present on the structures, thermally annealing the structures, and compacting the structures.

25. The process of claim 1, further comprising dispensing the amount of dispersion onto the surface.

26. The process of claim 1, wherein the process is performed in a continuous manner, the continuous manner optionally being a roll-to-roll process.

27. The process of claim 1, wherein the process is performed at or below about 80° C.

28. A structure, the structure made according to claim 1.

29. A system, comprising:
an amount of a dispersion comprising an aqueous solvent having a plurality of nanoparticles dispersed therein, the nanoparticles optionally having a diameter of from about 2 nm to about 1000 nm;
a template stamp having a pattern thereon;
a surface; and
an applicator, the applicator configured to dispense an amount of the dispersion onto the surface,
the system being configured to contact the template stamp to dispensed dispersion so as to give rise to structures that comprise the nanoparticles and substantially conform to the pattern of the template stamp.

30. A metasurface, comprising
a substrate; and
a plurality of structures superposed on the substrate,
a structure comprising a plurality of nanoparticles associated together,
a structure having a characteristic dimension in the range of from about 5 nm to about 1000 nm.

31. The metasurface of claim 30, wherein the structures are associated with an optical property of the metasurface, and comprise pillars, holes, or both.

32. The metasurface of claim 31, wherein the pillars are any one or more of circular in cross-section, bowtie in cross-section, polygonal in cross-section, or asymmetric in cross section.

33. The metasurface of claim 32, wherein the pillars are substantially circular in cross-section.

34. The metasurface of claim 30, wherein the substrate comprises a polymer.

35. The metasurface of claim 30, wherein the structures are dielectric materials.

36. The metasurface of claim 30, wherein the metasurface is configured to reflect light in any one or more of a visible range or an infrared range, the infrared range optionally being short wavelength infrared.

37. The metasurface of claim 36, wherein the metasurface is configured to reflect light in a visible range response to a physical change of the substrate.

38. The metasurface of claim 33, wherein the metasurface is integrated in a sensor component or sensor system.

39. The metasurface of claim 33, further comprising a residual film comprising the nanoparticles, the residual film disposed between the structures and the substrate.

40. A nanostructure imprinting process, comprising:
contacting a template stamp to an amount of a dispersion disposed on a surface,
the template stamp having a pattern thereon,
the dispersion (i) comprising a temperature-thinning solvent and (ii) having a plurality of nanoparticles dispersed therein, the nanoparticles optionally having a diameter of from about 2 nm to about 1000 nm, and
the contacting being performed such that the dispersion at least partially fills the pattern of the template stamp; and
effecting at least partial removal of the solvent so as to give rise to structures that comprise the nanoparticles and that substantially conform to the pattern of the template stamp,
the structures optionally defining a metasurface.

41. The nanostructure imprinting process of claim 40, wherein the temperature-thinning solvent comprises any one or more of terpineol or cresol, and further wherein the dispersion optionally comprises TiO₂ nanoparticles.

42. The nanostructure imprinting process of claim 40, wherein the temperature-thinning solvent has a viscosity greater than 2 centipoise at temperatures below about 20° C.

43. The nanostructure imprinting process of claim 40, wherein the temperature-thinning solvent has a viscosity of about 0.1 cP to about 50 cP at between 40 and 80° C.

44. The nanostructure imprinting process of claim 40, wherein the dispersion has a viscosity of from about 2 cP to about 100,000 cP at temperatures below 50° C.

45. The nanostructure imprinting process of claim 40, wherein the temperature-thinning solvent has a viscosity at room temperature of greater than 2 centipoise and less than about 100,000 cP.

46. The nanostructure imprinting process of claim 40, further comprising maintaining the template stamp in position while effecting removal of the solvent.

47. The nanostructure imprinting process of claim 40, wherein the structures contact the surface.

48. The nanostructure imprinting process of claim 40, wherein a structure defines a characteristic dimension in the range of from about 5 nm to about 1000 nm.

49. The nanostructure imprinting process of claim 40, wherein the imprinting process results in a stable structure with no residual layer of nanoparticles.

50. The nanostructure imprinting process of claim 40, wherein the imprinting process results in a stable structure with a residual film comprising the nanoparticles beneath the structures, the residual film having a thickness of from about 5 nm to about 25 μm.

51. The nanostructure imprinting process of claim 40, wherein the nanoparticles comprise any one or more of a metal, a metal oxide, a semiconductor, an insulator, or any combination thereof.

52. The nanostructure imprinting process of claim 40, wherein the nanoparticles are crystalline.

53. The nanostructure imprinting process of claim 40, wherein the nanoparticles are amorphous.

54. The nanostructure imprinting process of claim 40, wherein the nanoparticles comprise at least one of rutile TiO₂ and anatase TiO₂.

55. The nanostructure imprinting process of claim 40, wherein the nanoparticles comprise one or more ligands present thereon.

56. The nanostructure imprinting process of claim 40, further comprising any one or more of exchanging the ligands of the nanoparticles and removing the ligands of the nanoparticles.

57. The nanostructure imprinting process of claim 56, wherein the ligand exchange or removal is performed so as to adjust an optical property of the metasurface.
